(19) United States
(12) Patent Application Publication
(10) Pub. No.: US 2020/0250101 A1
(43) Pub. Date: Aug. 6, 2020

(54) SYSTEM AND METHOD FOR INTELLIGENT TILE-BASED MEMORY BANDWIDTH MANAGEMENT

(71) Applicant: QUALCOMM INCORPORATED, San Diego, CA (US)

(72) Inventors: GEORGE PATSILARAS, San Diego, CA (US); Wesley James Holland, La Jolla, CA (US); Bohuslav Rychlik, San Diego, CA (US); Andrew Edmund Turner, San Diego, CA (US); Jeffrey Shabel, San Diego, CA (US); Simon Peter William Booth, San Diego, CA (US); Simo Petteri Kangaslampi, San Diego, CA (US); Christopher Koob, Round Rock, TX (US); Wisnu Wurjantara, Toronto (CA); David Hansen, Calgary (CA); Ron Lieberman, Austin, TX (US); Daniel Palermo, Austin, TX (US); Colin Sharp, Cardiff, CA (US); Hao Liu, San Diego, CA (US)

(21) Appl. No.: 16/269,399

(22) Filed: Feb. 6, 2019

(51) Int. Cl. G06F 12/0893; G06F 12/06; G06F 3/06; H03M 7/30

(52) U.S. Cl. CPC G06F 12/0893; G06F 12/0623; G06F 3/0613; G06F 2212/305; G06F 3/0673; H03M 7/30; G06F 3/0656

(57) ABSTRACT

An intelligent tile-based memory bandwidth management solution executed by an address aperture, such as a compression address aperture, services linearly addressed data requests (read requests and write requests) from a processor to data stored in a memory component having a tile-based address structure. For read requests, the aperture stores previously read tiles (full or partial) in a tile-aware cache and then seeks to service future read requests from the cache instead of the long-term memory component. For write requests, the aperture stores the write data in the tile-aware cache and assembles the data with write data from other write requests so that full tile data writes to the long-term memory may be achieved in lieu of excessive partial-tile writes.

### DESCRIPTION OF THE RELATED ART

Portable computing devices (“PCDs”) are becoming necessities for people on personal and professional levels. These devices may include cellular telephones, portable digital assistants (“PDAs”), portable game consoles, palmtop computers, and other portable electronic devices. PCDs commonly contain integrated circuits, or systems on a chip (“SoC”), that include numerous components designed to work together to deliver functionality to a user. For example, a SoC may contain any number of processing engines such as modems, central processing units (“CPUs”) made up of cores, graphical processing units (“GPUs”), etc. that read and write data and instructions to and from memory components on the SoC. The data and instructions are transmitted between the devices via a collection of wires known as a bus.

The efficient sizing of bus bandwidth and memory components in a PCD is important for optimizing the functional capabilities of processing components on the SoC and guaranteeing a minimum required quality of service (“QoS”) level. Commonly, the utilization of memory capacity and bus bandwidth is further optimized by compressing data so that the data requires less bus bandwidth to transmit and less space in the memory for storage.

Often, processors are optimized for reading, writing and caching data in an uncompressed, linear manner (i.e., the data is consecutively addressed) while the memory component in which the data is stored in a compressed form is organized by image frames that are subdivided into tiles, each having a width of multiple words and a height of multiple data lines. The result of such a scenario is that performance of the system may suffer as a compression address aperture through which the data and instructions are transmitted between the processor and the memory component works to service a linearly addressed transaction from a non-linear, tile-based address of a memory component.

And so, when the processor makes a read request for linearly stored data, for example, the compression address aperture may be required to read a series of tiles in order to retrieve a given line of data, the given line of data having been stored across multiple adjacent tiles in an image frame. Similarly, when a second line of data is required to service a transaction, the aperture may retrieve the same tiles again, thereby causing inefficient use of bandwidth due to over-fetching of tiles. Therefore, there is a need in the art for improved systems and methods for servicing linearly addressed data transactions from compressed data stored in a tile-based memory component, More specifically, there is a need in the art for an intelligent tile-based memory bandwidth management system and method.

### SUMMARY OF THE DISCLOSURE

Various embodiments of methods and systems for intelligent tile-based memory bandwidth management in a portable computing device (“PCD”) are disclosed. An exemplary method begins by receiving at an address aperture a first data read request from a processing component. The first data read request may be associated with a first linear aperture address because the processing component is not aware of a tile-based address structure of a memory component, such as a DDR memory, that stores the requested data. In response to receiving the first data read request, the address aperture may determine a tile-based address in an alias address region of a memory component having a tile-based address structure. The tile-based address may be associated with one or more tiles containing data needed for service of the first data read request.

The address aperture may then determine whether the one or more tiles are stored in a tile-aware cache of the address aperture and, if so, the address aperture may respond to the first data read request by returning to the processor data from the one or more tiles stored in the tile-aware cache. Depending on embodiment, the address aperture may be a compression address aperture that includes a codec for compressing and decompressing data. A compression address aperture may thusly decompress data from a tile, or tiles, before returning it to the requesting processor.

If the address aperture determines that the one or more tiles needed to service the linear data request are unavailable in the tile-aware cache, then the address aperture may respond to the first data read request by reading the one or more tiles from the memory component and returning to the processor data from the one or more tiles read from the memory component. Advantageously, though, the address aperture may store the full or partial tiles in the tile-aware cache so that they are ready and available to service future read requests, thereby avoiding the need to retrieve the same tiles from the memory component at a later time for a later request. In this way, when the address aperture receives a second data read request from the processing component that is associated with a second aperture address, the address aperture may respond to the second data read request by returning to the processor data from the one or more tiles stored in the tile-aware cache that were read from the memory component in service of the first data request.

The address aperture according to the solution may also accommodate write requests from a processing component that is unaware of the tile-based address structure of a memory component. Servicing a write request(s) begins with receiving at the address aperture a first data write request from the processing component. In response to receiving the first data write request, the address aperture may determine a tile-based address in the alias address region of the memory component having a tile-based address structure. The tile-based address may be associated with one or more tiles that will be written to in service of the first data write request. Next, the address aperture may determine that service of the first data write request would require one or more partial tile writes to the memory component. And so, instead of executing partial tile writes, the aperture may store the write data (e.g., the “dirty” data) from the first data write request in the tile-aware cache. Then, when the address aperture later receives a second data write request (or requests) from the processing component that, when combined with write data from the first write request, would form one or more full tile write transactions, the address aperture may assemble the write data from the second data write request with the write data from the first data write request and write the assembled write transaction to the alias address region of the memory component having a tile-based address structure.

### BRIEF DESCRIPTION OF THE DRAWINGS

In the drawings, like reference numerals refer to like parts throughout the various views unless otherwise indicated. For reference numerals with letter character designations such as “102A” or “102B”, the letter character designations may differentiate two like parts or elements present in the same figure. Letter character designations for reference numerals may be omitted when it is intended that a reference numeral encompass all parts having the same reference numeral in all figures.

FIG. 1 illustrates the effects of compressing an image frame composed of multiple data sub-units or tiles;

FIG. 2 illustrates a portion of a compressed image frame comprised of tiles and the relative latencies associated with reading data lines that each traverse a series of the tiles;

FIG. 3 is a functional block diagram illustrating an exemplary embodiment of an on-chip system configured for intelligent tile-based memory bandwidth management according to the solution;

FIG. 4 is a logical flowchart illustrating the service of a read request by an exemplary embodiment of a method for intelligent tile-based memory bandwidth management according to the solution;

FIG. 5 is a logical flowchart illustrating the service of a write request by an exemplary embodiment of a method for intelligent tile-based memory bandwidth management according to the solution;

FIG. 6 is a functional block diagram illustrating an exemplary, non-limiting aspect of a portable computing device (“PCD”) in the form of a wireless telephone for implementing intelligent tile-based memory bandwidth management methods and systems according to the solution; and

FIG. 7 is a schematic diagram illustrating an exemplary software architecture of the PCD of FIG. 6 for executing intelligent tile-based memory bandwidth management methodologies.

### DETAILED DESCRIPTION

The word “exemplary” is used herein to mean serving as an example, instance, or illustration. Any aspect described herein as “exemplary” is not necessarily to be construed as exclusive, preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

In this description, reference to “DRAM” or “DDR” memory components will be understood to envision any of a broader class of volatile random access memory (“RAM”) and will not limit the scope of the solutions disclosed herein to a specific type or generation of RAM. That is, it will be understood that various embodiments of the systems and methods provide a solution for managing transactions of data that have been compressed, stored and retrieved according to intelligent tile-based prefetching methodologies and are not necessarily limited in application to data transactions associated with double data rate memory. Moreover, it is envisioned that certain embodiments of the solutions disclosed herein may be applicable to DDR, DDR-2, DDR-3, low power DDR (“LPDDR”) or any subsequent generation of DRAM.

As used in this description, the terms “component,” “database,” “module,” “block,” “system,” “aperture,” and the like are intended to refer generally to a computer-related entity, either hardware, firmware, a combination of hardware and software, software, or software in execution, unless specifically limited to a certain computer-related entity. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “central processing unit (“CPU”),” “digital signal processor (“DSP”),” “graphical processing unit (“GPU”),” and “chip” are used interchangeably. Moreover, a CPU, DSP, GPU or chip may be comprised of one or more distinct processing components generally referred to herein as “core(s).”

In this description, the terms “engine,” “processing engine,” “processing component,” “processor,” “producer” and the like are used to refer to any component within a system on a chip (“SoC”) that generates data and/or image frames and transfers them over a bus to, or from, a memory component via a compression address aperture and/or in cooperation with any other functional aperture. As such, an engine may refer to, but is not limited to refer to, a CPU, DSP, GPU, modem, controller, camera, video recorder, etc.

In this description, the term “bus” refers to a collection of wires through which data is transmitted from a processing engine to a memory component or other device located on or off the SoC. It will be understood that a bus consists of two parts an address bus and a data bus where the data bus transfers actual data and the address bus transfers information specifying location of the data in a memory component (i.e., address and associated metadata). The terms “width” or “bus width” or “bandwidth” refers to an amount of data, i.e. a “chunk size,” that may be transmitted per cycle through a given bus. For example, a 16-byte bus may transmit 16 bytes of data at a time, whereas 32-byte bus may transmit 32 bytes of data per cycle. Moreover, “bus speed” refers to the number of times a chunk of data may be transmitted through a given bus each second and, as such, would be understood by one of ordinary skill in the art to relate to “bus capacity.” Similarly, a “bus cycle” or “cycle” refers to transmission of one chunk of data through a given bus.

In this description, the term “portable computing device” (“PCD”) is used to describe any device operating on a limited capacity power supply, such as a battery. Although battery operated PCDs have been in use for decades, technological advances in rechargeable batteries coupled with the advent of third generation (“3G”) and fourth generation (“4G”) and fifth generation (“5G”) wireless technology have enabled numerous PCDs with multiple capabilities. Therefore, a PCD may be a cellular telephone, a satellite telephone, a pager, a PDA, a smartphone, a navigation device, a smartbook or reader, a media player, a combination of the aforementioned devices, a laptop computer with a wireless connection, among others.

In this description, the terms “image,” “data set,” “data,” “frame,” “image frame,” “buffer,” “file” and the like are used interchangeably.

In this description, the terms “tile” and “unit” are used interchangeably to refer to a block of pixels that forms a subset of a larger block of data such as an image frame. A “tile” or “unit,” depending upon embodiment of the solution, may exhibit any aspect ratio suitable for the embodiment and, as such, one of ordinary skill in the art will appreciate that a “tile” or “unit” within an image frame is not necessarily limited to having a “square” aspect ratio—I.e., depending upon embodiment a “tile” or “unit” may be rectangular.

In this description, the term “uncompressed” refers to a frame in its original, pre-compression state whereas the term “decompressed” refers to a frame that was first compressed from its uncompressed state via a compression address aperture and then later decompressed by the aperture in service to a read request from a processor. Depending on the class of compression used, the data set of a decompressed frame may be identical to the data set of the frame's original, uncompressed state (lossless compression) or it may not (lossy compression), as would be understood by one of ordinary skill in the art.

As one of ordinary skill in the art would understand and appreciate, an address aperture component provides access to a memory region through an alternate address range. Typically, an address aperture leverages a simple mapping between the addresses it uses (“aperture addresses”) and the original addresses used by a processor (“alias addresses”) for the same physical memory locations. A functional address aperture is an address aperture that additionally performs some function on the data as it passes through the aperture from the processor to the memory component. Example functions that may be provided by a functional address aperture include, but are not limited to, encryption, compression and error correction.

Functional address apertures, by virtue of compressing and/or manipulating the data, may introduce a relatively complex mapping between data in the aperture domain versus data in the alias domain. That is, address mapping between the domains may not be 1:1—an address region in the aperture space may correspond to a smaller or larger region in the aliased address space (as might be expected, for example, in the case of a functional address aperture implementing compression). As one of ordinary skill in the art would appreciate, a single data access in the aperture space may correspond to zero, one, or multiple accesses in the aliased space (perhaps even to non-contiguous memory ranges). Moreover, the functional address aperture may leverage a cache such that accesses in the aperture space are delayed or coalesced, as the need may be.

It is envisioned that a functional address aperture may be configured and leveraged to implement a tile-aware compression function such that data written to memory through the aperture may be compressed in view of the tile-based organization of the memory component (such as the DDR). A benefit of such a functional address aperture is that memory bandwidth compression and tile management in the memory component may be accomplished without the producing processor being sensitive to compression function and tile size. Such a functional address aperture may be configured to map a linear-addressed aperture address region to a tile-addressed alias address region for one or more buffers, accommodate partial-tile read requests, and cache any remaining tile data for later reads (thereby mitigating over-fetch of tiles from the memory). Similarly, such a functional address aperture may be configured to cache write data and/or collect and assemble partial tile writes into complete tiles for efficient compression.

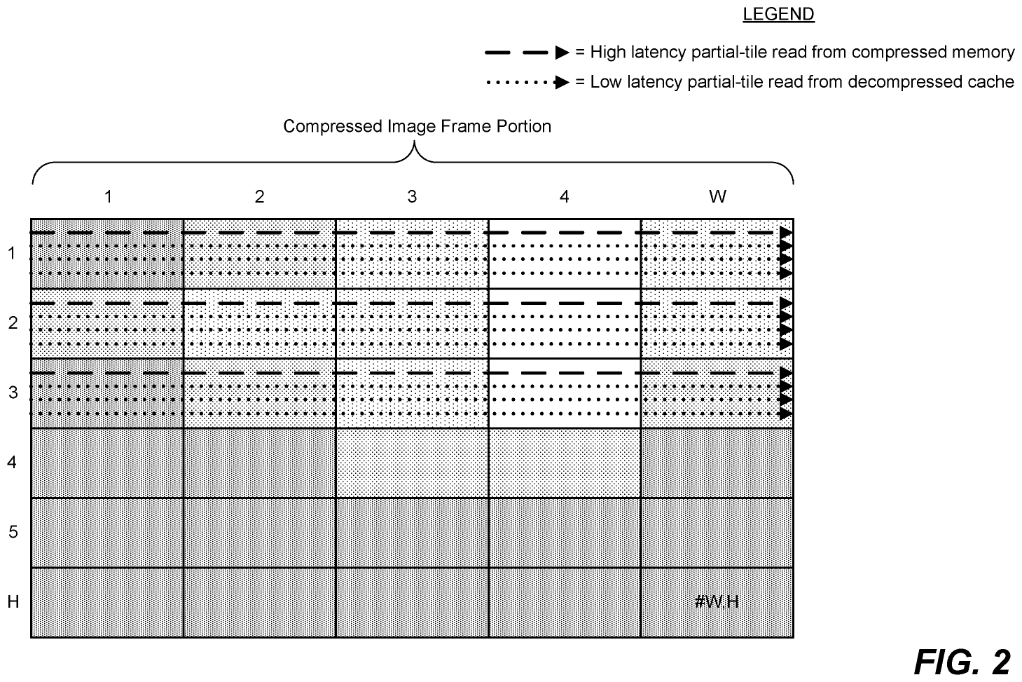

As mentioned above, it is envisioned that a tile-aware cache in a compression address aperture may mitigate over-fetch and, in so doing, mitigate unnecessary consumption of memory bandwidth. A compression address aperture according to the solution, in response to a read request issued by a processor, may 1) fetch a programmable lookup data structure from memory in order to determine the associated buffer/tile mapping for the request, 2) check the tile-aware cache to make sure that the identified frame/tiles are not in the cache already, 3) fetch the identified frame/tiles from compressed memory (if not already in the cache), and 4) decompress the compressed frame/tiles. Advantageously, once the tiles are fetched, any subsequent reads to the data stored in those tiles will be serviced by the aperture with relatively low latency, as the tiles would already be in the tile-aware cache (thereby avoiding step 3 and possibly step 4 as described above). A more detailed explanation of the relative latencies that may be experienced by a compression address aperture seeking to make a partial-tile read is provided below relative to FIG. 2.

Briefly, embodiments of the proposed solution for an intelligent tile-based memory bandwidth management system and method leverage a functional address aperture to implement a tile-aware compression function. A benefit of the solution is that memory bandwidth compression and tile management may be accomplished without the processor hardware and/or software being aware of, or sensitive to, a required compression function or tile size of the memory component. Embodiments of a compression address aperture according to the solution may be configured to, among other functions, map a linear-addressed aperture address region to a tile-addressed alias address region for one or more buffers, accommodate partial-tile read requests, cache remaining tile data after partial-tile reads in an effort to service subsequent read requests and mitigate tile overfetch, cache write data, collect/assemble partial tile writes into complete tiles for compression, etc.

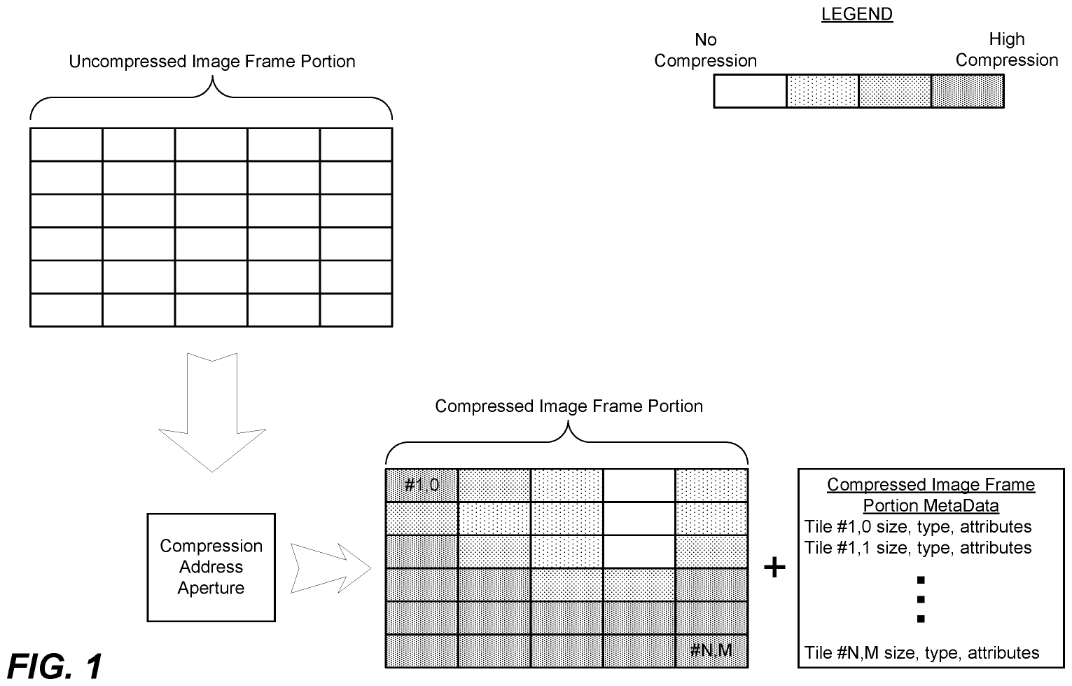

Turning to FIG. 1, illustrated are the effects of compressing an image frame composed of multiple data sub-units or tiles. In this description, the various embodiments may be described within the context of an image frame, or portion of an image frame, made up of 256-byte tiles. Notably, however, it will be understood that the 256-byte tile sizes, as well as the various compressed data transaction sizes, are exemplary in nature and do not suggest that embodiments of the solution are limited in application to 256-byte tile sizes. Moreover, it will be understood that reference to any specific minimum access length (“MAL”) or access block size (“ABS”) for a DRAM in this description is being used for the convenience of describing the solution and does not suggest that embodiments of the solution are limited in application to a DRAM device having a particular MAL requirement. As such, one of ordinary skill in the art will recognize that the particular data transfer sizes, chunk sizes, bus widths, MALs, etc. that may be referred to in this description are offered for exemplary purposes only and do not limit the scope of the envisioned solutions as being applicable to applications having the same data transfer sizes, chunk sizes, bus widths, MALs, etc.

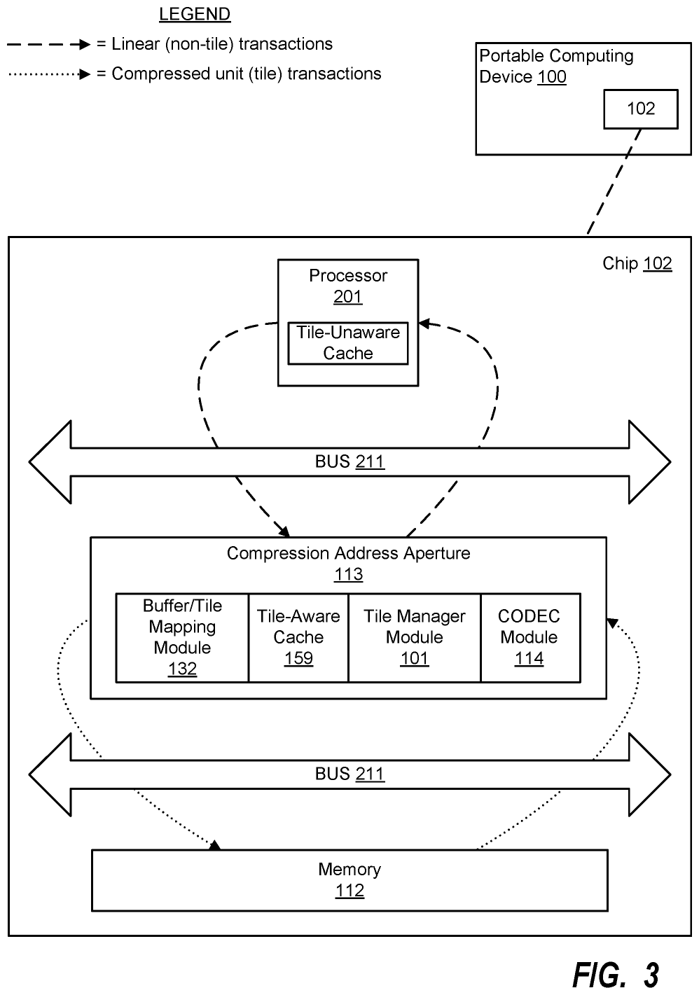

Returning to the FIG. 1 illustration, a portion of an uncompressed image frame (aka, a “buffer”) is depicted as being comprised of thirty uncompressed tiles or units, each of a size “X” as represented by a lack of shading. An exemplary size X may be 256 bytes, however, as explained above, a tile is not limited to any certain size and may vary according to application. For ease of illustration and description, the thirty tile portion of the larger uncompressed image frame is depicted as representative of the entire image frame. As would be understood by one of ordinary skill in the art, the uncompressed image frame may be reduced in size, thereby optimizing its transfer over a bus, reducing overall system power consumption and minimizing its impact on memory capacity, by a compressor block (depicted in FIG. 3 as Image CODEC Module 114) in a compression address aperture that applies a compression algorithm on a tile by tile basis. The result of the compression is a compressed image frame plus a metadata file, as can be seen in the FIG. 1 illustration relative to the illustrated portion of the frame. The compressed image frame is comprised of the tiles in the original, uncompressed image frame after having been subjected to a compression algorithm by the compression block 114.

In the uncompressed image frame, each tile may be of a size X, whereas in the compressed image frame each tile may be of a size X or less (X for no compression possible, X-1 bytes, X-2 bytes, X-3 bytes, . . . , X===1 byte). In the illustration, the various tiles that form the compressed image frame are represented by differing levels of shading depending on the extent of compression that resulted from the compression block 114 having applied its compression algorithm to the data held by the given tile. Notably, the compression block 114 creates a companion buffer for a compressed image frame metadata, as would be understood by one of ordinary skill in the art. The compressed image frame metadata contains a record of the size, type and attributes for each compressed tile in the compressed image frame. Because MUM access may be limited to units of the minimum access length MAL, the size of a given compressed tile may be represented in the metadata as the number of ABSs required to represent the compressed tile size (e.g., 1 MAL, 2 MAL, . . . n MAL). This size description in the metadata allows a future reader of the buffer to ask the memory for only the minimum required amount of data needed to decompress each tile back to the original size X.

FIG. 2 illustrates a portion of a compressed image frame comprised of tiles and the relative latencies associated with reading data lines that each traverse a series of the tiles. The exemplary compressed image frame portion is organized into a grid of compressed tiles having W columns and H rows. As a way of illustration, assuming a 4×4 pixel size for each tile, a processor executing a naïve raster-order access across the frame will generate a high memory latency for one whole line (e.g., dash arrow traversing the columns from tile #1,#1 to tile #W,#1), followed by lower memory latency for reads of the three subsequent lines from the same series of tiles (e.g., dotted arrows traversing the columns from tile #1,#1 to tile #W,#1). The reason for the lower memory latency for the subsequent line reads is because, advantageously, embodiments of the solution may have saved the tiles in cache after previously retrieving the tiles from memory in order to accommodate the first line read. The pattern repeats with linear reads of data tiles #1,#2 to tile #W,#2, tiles #1,#3 to tile #W,#3, etc. Advantageously, and as will be better understood from the following description and figures, embodiments of the solution reduce latency for subsequent line reads by storing tiles in a tile-aware cache after servicing an initial partial-tile read. Also, and as will be better understood from the following description and figures, embodiments of the solution may aggregate and assemble partial-tile writes in a tile-aware cache and only compress the tiles and write them to long term memory when full-tile writes are possible. In these ways, memory bandwidth and compression may be optimized by avoiding or mitigating 1) multiple fetches of a given tile to accommodate multiple partial-tile reads and 2) compression and writing of transactions representing less than full-tile data blocks.

Turning now to the remaining figures, embodiments of the solution are further described. As will become evident from the following figures and the related description, compressed image frames sub-divided into tiles may be intelligently managed in response to linear access requests such that tiles are present in a tile-aware cache of a compressed address aperture when needed to service a later access request. Embodiments of the solution also hold linear write transactions in a tile-aware cache of a compression address aperture in order to assemble the write transactions into full-tile writes. In this way, embodiments of the solution mitigate or avoid long latency times for servicing partial-tile reads from tile-unaware processors without risking significant overfetch of tiles. Further, embodiments of the solution optimize bandwidth utilization and compression efforts by minimizing overfetch and avoiding partial-tile writes.

FIG. 3 is a functional block diagram illustrating an exemplary embodiment of an on-chip system 102 configured for intelligent tile-based memory bandwidth management according to the solution. As can be understood from the FIG. 3 illustration, a processor 201 and a compression address aperture 113 communicate with each other and a memory component 112 over a bus 211. The processor 201 is associated with a tile-unaware cache and, as such, may make data requests from memory 112 using a linear (non-tile) address provided to compression address aperture 113. The compression address aperture 113 may utilize a buffer/tile mapping module 132 in order to access a lookup table (lookup table not depicted in the FIG. 3 illustration and may reside in memory 112 or some other memory component residing on or off chip 102). Using the lookup table, the buffer/tile mapping module 132 of the aperture 113 may determine the aperture address that maps to the linear address provided by the processor 201. With the aperture address determined, the compression address aperture 113 may query memory 112 to retrieve the requested data in its compressed form.

Notably, the compressed data may be stored in memory 112 across a series of tiles and, as such, to return the linear data requested by the processor 201 the aperture 113 may be required to make partial reads of multiple tiles in memory 112. As explained above, when partial reads of multiple tiles are required in order to service a linear data request, the first line of data may experience a relatively high latency as multiple tiles must be retrieved from memory 112 into tile-aware cache 159 and decompressed by codec 114 before the line of data may be returned to the processor 201. To reduce the latency associated with acquiring subsequent lines of data that traverses across multiple tiles of memory 112, the aperture 113 may store the tiles in cache 159 so that re-fetching of the tiles is unnecessary in order to service subsequent data reads.

Returning to the FIG. 3 illustration, the tile manager module (“TM module”) 101 may begin fetching of compressed tiles that contain the linear data requested by processor 201. The fetched compressed tiles may be decompressed by codec 114 and stored in tile-aware cache 159 in their decompressed state or, optionally depending on embodiment of the solution, may be stored in tile-aware cache 159 in their compressed state and later decompressed by codec 114. Regardless, once decompressed, the partial reads of the tiles may be aggregated and returned to processor 201 in response to the linear request made by the processor 201. In this way, even though the processor 201 is unaware of the tile-based organization of the compressed image in memory 112, the compression address aperture 113 may service a linear address request from processor 201.

Advantageously, as the processor 201 continues to make linear data requests, and the compression address aperture 113 continues to respond to the requests as described above, the TM module 101 may query the tile-aware cache 159 to determine if the needed tiles are in the cache, thereby alleviating any overfetch. In this way, the TM module 101 may advantageously anticipate the need for certain compressed tiles to service future linear data requests from the processor 201 and, in so doing, mitigate or lower the average latency to service the data requests while reducing unnecessary burden on memory and bus bandwidth that could result from unnecessary fetches.

The TM module 101 may also accommodate linear write requests from processor 201 by storing the write data in tile-aware cache 159 and, based on query of a lookup table by buffer/tile mapping module 132, delaying partial-tile write transactions to memory 112 until full-tile writes can be serviced. That is, the TM module 101 may assemble multiple linear write requests into a full-tile write transaction.

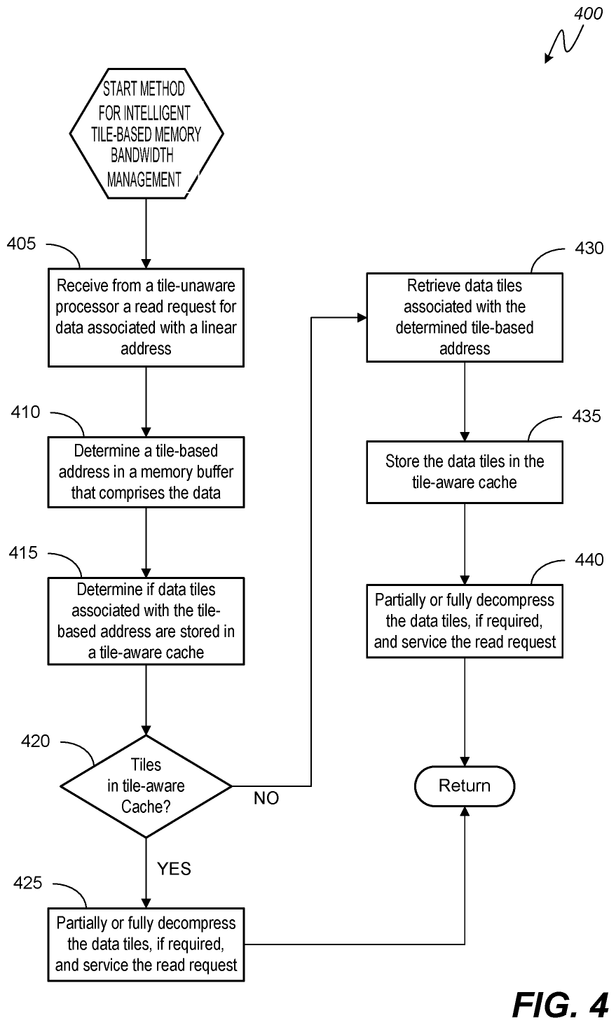

FIG. 4 is a logical flowchart illustrating the service of a read request by an exemplary embodiment of a method 400 for intelligent tile-based memory bandwidth management according to the solution. Beginning at block 405, the compression address aperture 113 may receive from a tile-unaware processor 201 a read request for data associated with a linear aperture address. Next, at block 410, the compression address aperture 113 may determine a tile-based alias address in the buffer 112 that comprises the compressed data needed in order to service the read request. It is envisioned that the mapping of the linear address to the tile-based address of the buffer may be accomplished any number of ways including, but not necessarily limited to, using a limited number of pre-programmable address range check registers in the compression address aperture that define the linear address to tile-based buffer lookup table, using a programmable lookup data structure stored in DRAM or cache and fetched on-demand, and/or using a direct encoding of the buffer index and X/Y offset into the linear address by leveraging the X/Y aperture concept.

Returning to the method 400 at block 415, the method 400 first determines if the data tiles of the tile-based alias address have been previously fetched to service a previous read request and are stored in a tile-aware cache 159 of the compression address aperture 113. From block 415, the method 400 moves to decision block 420. At decision block 420, if the needed tiles are in the tile-aware cache 159, no fetch of the tiles from memory 112 is required and so the “yes” branch is followed to block 425 and the data in the tiles is partially or fully decompressed from the tiles in the tile-aware cache 159 (if not already decompressed) and provided to the processor 201 in service to the read request. From block. 425, the method 400 returns.

Returning to decision block 420, if the needed tiles are not in the tile-aware cache 159, the method 400 follows the “no” branch to block 430 and the data tiles in memory 112 containing the data required to service the read request from processor 201 are retrieved from the tile-based address of memory 112. Next, at block 435, the data tiles are stored in the tile-aware cache 159 in anticipation of being needed to service future read requests. At block 440, the data in the tiles is partially or fully decompressed, if not already in a decompressed state, and provided to the processor 201 in service to the read request. The method 400 returns.

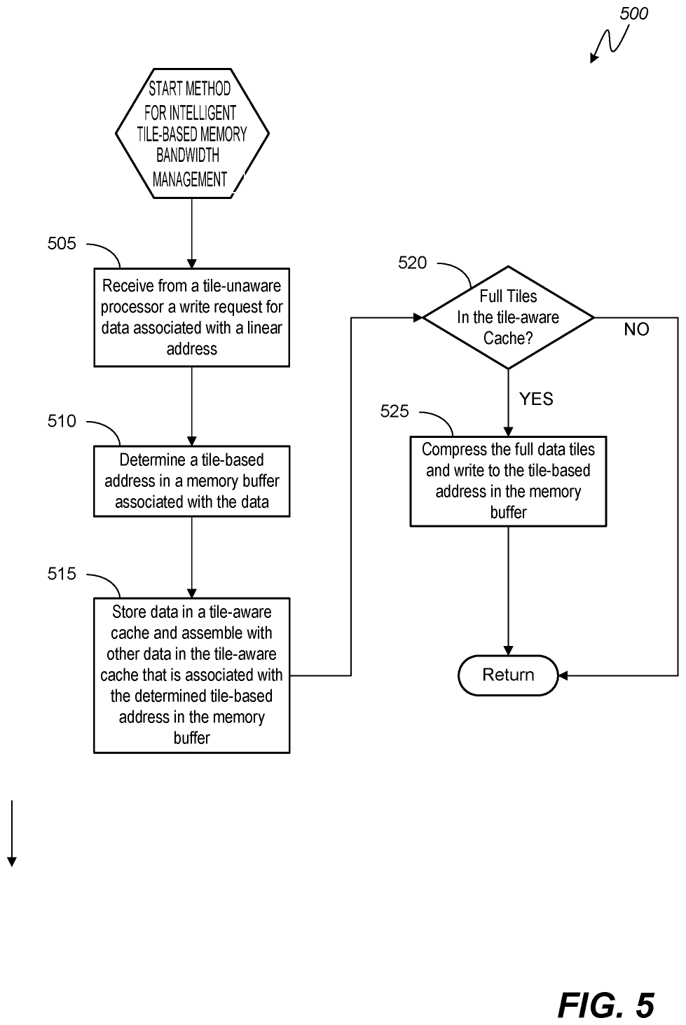

FIG. 5 is a logical flowchart illustrating the service of a write request by an exemplary embodiment of a method 500 for intelligent tile-based memory bandwidth management according to the solution. Beginning at block 505, the compression address aperture 113 may receive from a tile-unaware processor 201 a write request for data associated with a linear aperture address. Next, at block 510, the compression address aperture 113 may determine a tile-based alias address in memory 112 that is associated with the write data. At block 515, the data of the write request may be stored in the tile-aware cache 159 of the compression address aperture 113 and assembled with other data in the cache 159 designated to be written to the memory 112 and also associated with the tile-based alias address. The method 500 moves to decision block 520 and it is determined whether one or more full-tiles of data are assembled and ready for compression and writing to the memory 112. If no full-tiles are assembled, the method 500 follows the “no” branch and the method returns. If one or more full tiles are assembled, from decision block 520 the method 500 follows the “yes” branch to block 525.

At block 525, the one or more assemblies of linear data forming one or more full tiles of data are compressed and written to the appropriate tile-based address in the alias range of memory 112. In this way, embodiments of the solution avoid partial-tile compression and writes to the memory 112 when the tile-unaware processor is issuing linear write requests that don't by themselves map to a full tile block of compressed data,

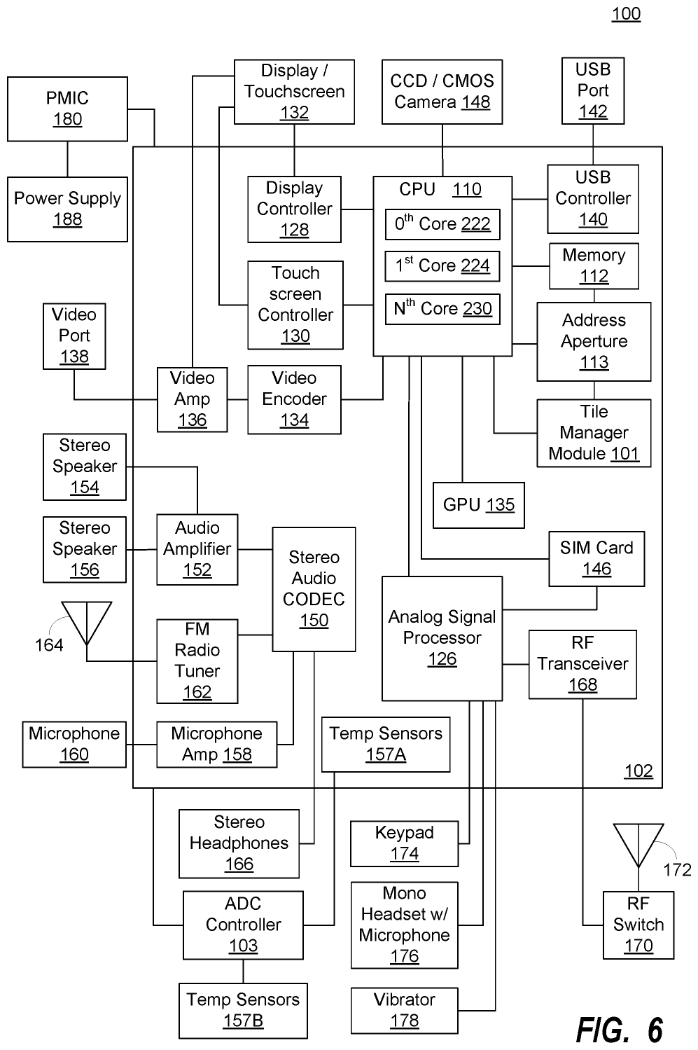

FIG. 6 is a functional block diagram illustrating an exemplary, non-limiting aspect of a portable computing device (“PCD”) 100 in the form of a wireless telephone for implementing intelligent tile-based memory bandwidth management methods and systems according to the solution. As shown, the PCD 100 includes an on-chip system 102 that includes a multi-core central processing unit (“CPU”) 110 and an analog signal processor 126 that are coupled together. The CPU 110 may comprise a zeroth core 222, a first core 224, and an Nth core 230 as understood by one of ordinary skill in the art. Further, instead of a CPU 110, a digital signal processor (“DSP”) may also be employed as understood by one of ordinary skill.

In general, tile manager (“TM”) module 101 may be formed from hardware and/or firmware and may be responsible for intelligent tile-based memory bandwidth management. The TM module 101 may be coupled to, or a part of, compression address aperture 113. As illustrated in FIG. 6, a display controller 128 and a touch screen controller 130 are coupled to the digital signal processor 110. A touch screen display 132 external to the on-chip system 102 is coupled to the display controller 128 and the touch screen controller 130. PCD 100 may further include a video encoder 134, e.g., a phase-alternating line (“PAL”) encoder, a sequential couleur avec memoire (“SECAM”) encoder, a national television system(s) committee (“NTSC”) encoder or any other type of video encoder 134. The video encoder 134 is coupled to the multi-core CPU 110. A video amplifier 136 is coupled to the video encoder 134 and the touch screen display 132. A video port 138 is coupled to the video amplifier 136. As depicted in FIG. 6, a universal serial bus (“USB”) controller 140 is coupled to the CPU 110. Also, a USB port 142 is coupled to the USB controller 140.

A memory 112, which may include a PoP memory, a cache, a mask ROM/Boot ROM, a boot OTP memory, a type DDR of DRAM memory, etc. may also be coupled to the CPU 110. A subscriber identity module (“SIM”) card 146 may also be coupled to the CPU 110, Further, as shown in FIG. 6, a digital camera 148 may be coupled to the CPU 110. In an exemplary aspect, the digital camera 148 is a charge-coupled device (“CCD”) camera or a complementary metal-oxide semiconductor (“CMOS”) camera.

As further illustrated in FIG. 6, a stereo audio CODEC 150 may be coupled to the analog signal processor 126. Moreover, an audio amplifier 152 may be coupled to the stereo audio CODEC 150. In an exemplary aspect, a first stereo speaker 154 and a second stereo speaker 156 are coupled to the audio amplifier 152. FIG. 6 shows that a microphone amplifier 158 may be also coupled to the stereo audio CODEC 150. Additionally, a microphone 160 may be coupled to the microphone amplifier 158. In a particular aspect, a frequency modulation (“FM”) radio tuner 162 may be coupled to the stereo audio CODEC 150. Also, an FM antenna 164 is coupled to the FM radio tuner 162. Further, stereo headphones 166 may be coupled to the stereo audio CODEC 150.

FIG. 6 further indicates that a radio frequency (“RF”) transceiver 168 may be coupled to the analog signal processor 126. An RF switch 170 may be coupled to the RF transceiver 168 and an RF antenna 172. As shown in FIG. 6, a keypad 174 may be coupled to the analog signal processor 126. Also, a mono headset with a microphone 176 may be coupled to the analog signal processor 126. Further, a vibrator device 178 may be coupled to the analog signal processor 126. FIG. 6 also shows that a power supply 188, for example a battery, is coupled to the on-chip system 102 through a power management integrated circuit (“PMIC”) 180. In a particular aspect, the power supply 188 includes a rechargeable DC battery or a DC power supply that is derived from an alternating current (“AC”) to DC transformer that is connected to an AC power source.

The CPU 110 may also be coupled to one or more internal, on-chip thermal sensors 157A as well as one or more external, off-chip thermal sensors 157B. The on-chip thermal sensors 157A may comprise one or more proportional to absolute temperature (“PTAT”) temperature sensors that are based on vertical PNP structure and are usually dedicated to complementary metal oxide semiconductor (“CMOS”) very large-scale integration (“VLSI”) circuits. The off-chip thermal sensors 157B may comprise one or more thermistors. The thermal sensors 157 may produce a voltage drop that is converted to digital signals with an analog-to-digital converter (“ADC”) controller (not shown). However, other types of thermal sensors 157 may be employed.

The touch screen display 132, the video port 138, the USB port 142, the camera 148, the first stereo speaker 154, the second stereo speaker 156, the microphone 160, the FM antenna 164, the stereo headphones 166, the RF switch 170, the RF antenna 172, the keypad 174, the mono headset 176, the vibrator 178, thermal sensors 157B, the PMIC 180 and the power supply 188 are external to the on-chip system 102. It will be understood, however, that one or more of these devices depicted as external to the on-chip system 102. in the exemplary embodiment of a PCD 100 in FIG. 6 may reside on chip 102 in other exemplary embodiments.

In a particular aspect, one or more of the method steps described herein may be implemented by executable instructions and parameters stored in the memory 112 or as form the TM module 101 and/or the compression address aperture 113 in general (see FIG. 3). Further, the TM module 101, the aperture 113 in general (which includes CODEC module 114, tile-aware cache 159 and buffer/tile mapping module 132), the memory 112, the instructions stored therein, or a combination thereof may serve as a means for performing one or more of the method steps described herein.

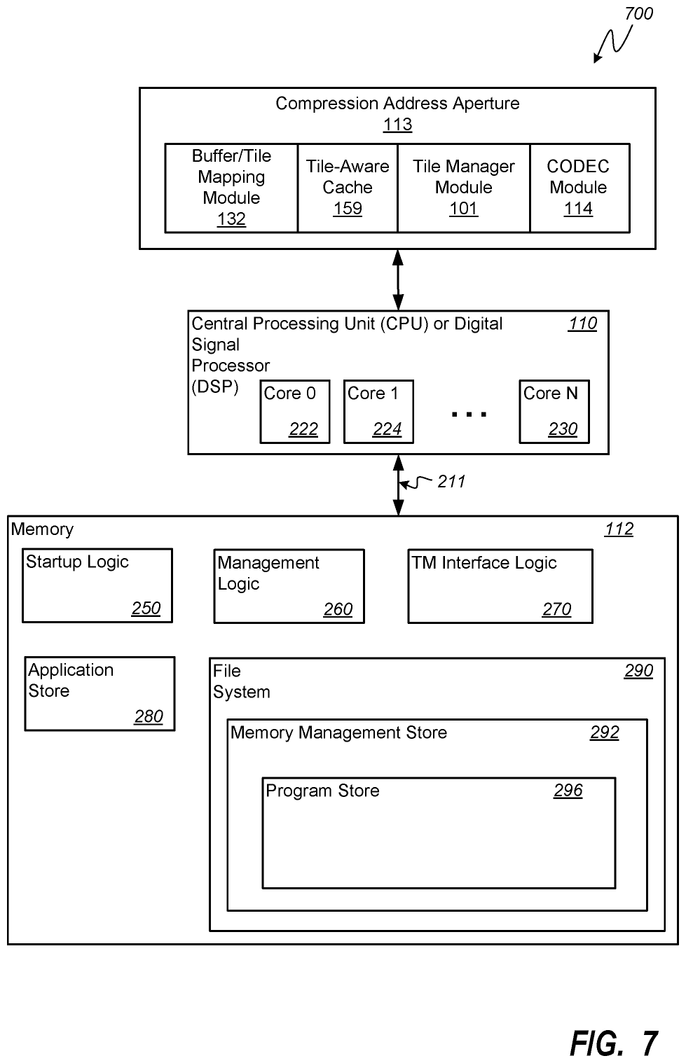

FIG. 7 is a schematic diagram illustrating an exemplary software architecture of the PCD of FIG. 6 for executing intelligent tile-based memory bandwidth management methodologies. As illustrated in FIG. 7, the CPU or digital signal processor 110 is coupled to the memory 112 via main bus 211. The CPU 110, as noted above, is a multiple-core processor having N core processors. That is, the CPU 110 includes a first core 222, a second core 224, and an N^{th} core 230. As is known to one of ordinary skill in the art, each of the first core 222, the second core 224 and the N^{th} core 230 are available for supporting a dedicated application or program. Alternatively, one or more applications or programs may be distributed for processing across two or more of the available cores.

The CPU 110 may receive commands from one or more of the modules of compression address aperture 113 that may comprise software and/or hardware. If embodied as software, the module(s) comprise instructions that are executed by the CPU 110 that issues commands to other application programs being executed by the CPU 110 and other processors.

The first core 222, the second core 224 through to the Nth core 230 of the CPU 110 may be integrated on a single integrated circuit die, or they may be integrated or coupled on separate dies in a multiple-circuit package. Designers may couple the first core 222, the second core 224 through to the N^{th} core 230 via one or more shared caches and they may implement message or instruction passing via network topologies such as bus, ring, mesh and crossbar topologies.

Bus 211 may include multiple communication paths via one or more wired or wireless connections, as is known in the art and described above in the definitions. The bus 211 may have additional elements, which are omitted for simplicity, such as controllers, buffers (caches), drivers, repeaters, and receivers, to enable communications. Further, the bus 211 may include address, control, and/or data connections to enable appropriate communications among the aforementioned components.

When the logic used by the PCD 100 is implemented in software, as is shown in FIG. 7, it should be noted that one or more of startup logic 250, management logic 260, TM interface logic 270, applications in application store 280 and portions of the file system 290 may be stored on any computer-readable medium for use by, or in connection with, any computer-related system or method.

In the context of this document, a computer-readable medium is an electronic, magnetic, optical, or other physical device or means that may contain or store a computer program and data for use by or in connection with a computer-related system or method. The various logic elements and data stores may be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device.

The computer-readable medium can be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection (electronic) having one or more wires, a portable computer diskette (magnetic), a random-access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, for instance via optical scanning of the paper or other medium, then compiled, interpreted or otherwise processed in a suitable manner if necessary, and then stored in a computer memory.

In an alternative embodiment, where one or more of the startup logic 250, management logic 260 and perhaps the TM interface logic 270 are implemented in hardware, the various logic may be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The memory 112 is a non-volatile data storage device such as a flash memory or a solid-state memory device. Although depicted as a single device, the memory 112 may be a distributed memory device with separate data stores coupled to the digital signal processor 110 (or additional processor cores).

The startup logic 250 includes one or more executable instructions for selectively identifying, loading, and executing a select program for intelligent tile-based memory bandwidth management. The startup logic 250 may identify, load and execute a select intelligent tile-based memory bandwidth management program. An exemplary select program may be found in the program store 296 of the embedded file system 290. The exemplary select program, when executed by one or more of the core processors in the CPU 110 may operate in accordance with one or more signals provided by the compression address aperture 113 to implement intelligent tile-based memory bandwidth management methodologies.

The management logic 260 includes one or more executable instructions for terminating an intelligent tile-based memory bandwidth management program on one or more of the respective processor cores, as well as selectively identifying, loading, and executing a more suitable replacement program. The management logic 260 is arranged to perform these functions at run time or while the PCD 100 is powered and in use by an operator of the device. A replacement program may be found in the program store 296 of the embedded file system 290.

The interface logic 270 includes one or more executable instructions for presenting, managing and interacting with external inputs to observe, configure, or otherwise update information stored in the embedded file system 290. In one embodiment, the interface logic 270 may operate in conjunction with manufacturer inputs received via the USB port 142. These inputs may include one or more programs to be deleted from or added to the program store 296. Alternatively, the inputs may include edits or changes to one or more of the programs in the program store 296. Moreover, the inputs may identify one or more changes to, or entire replacements of one or both of the startup logic 250 and the management logic 260. By way of example, the inputs may include a change to the tile size or compression algorithm associated with a particular intelligent tile-based memory bandwidth management algorithm.

The interface logic 270 enables a manufacturer to controllably configure and adjust an end user's experience under defined operating conditions on the PCD 100. When the memory 112 is a flash memory, one or more of the startup logic 250, the management logic 260, the interface logic 270, the application programs in the application store 280 or information in the embedded file system 290 may be edited, replaced, or otherwise modified. In some embodiments, the interface logic 270 may permit an end user or operator of the PCD 100 to search, locate, modify or replace the startup logic 250, the management logic 260, applications in the application store 280 and information in the embedded file system 290. The operator may use the resulting interface to make changes that will be implemented upon the next startup of the PCD 100. Alternatively, the operator may use the resulting interface to make changes that are implemented during run time.

The embedded file system 290 includes a hierarchically arranged memory management store 292. In this regard, the file system 290 may include a reserved section of its total file system capacity for the storage of information for the configuration and management of the various intelligent tile-based memory bandwidth management algorithms used by the PCD 100.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example. Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the drawings, which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer.

Therefore, although selected aspects have been illustrated and described in detail, it will be understood that various substitutions and alterations may be made therein without departing from the spirit and scope of the present invention, as defined by the following

What is claimed is:

1. A method for intelligent tile-based memory bandwidth management in a portable computing device (“PCD”), the method comprising:
receiving at an address aperture a first data read request from a processing component, wherein the first data read request is associated with a first linear aperture address;
in response to receiving the first data read request, the address aperture determining a tile-based address in an alias address region of a memory component having a tile-based address structure, wherein the tile-based address is associated with one or more tiles containing data needed for service of the first data read request;
the address aperture determining whether the one or more tiles are stored in a tile-aware cache of the address aperture; and
if the one or more tiles are stored in the tile-aware cache of the address aperture, the address aperture responding to the first data read request by returning to the processor data from the one or more tiles stored in the tile-aware cache.

2. The method of claim 1, wherein the address aperture comprises a codec and the data from the one or more tiles stored in the tile-aware cache is decompressed before being returned to the processor.

3. The method of claim 1, further comprising:
if the one or more tiles are unavailable in the tile-aware cache of the address aperture, the address aperture responding to the first data read request by reading the one or more tiles from the memory component and returning to the processor data from the one or more tiles read from the memory component.

4. The method of claim 3, further comprising:
storing at least part of the one or more tiles in the tile-aware cache, wherein the at least part of the one or more tiles was not required for service of the first read request.

5. The method of claim 4, further comprising:
receiving at the address aperture a second data read request from the processing component, wherein the second data read request is associated with a second aperture address; and
the address aperture responding to the second data read request by returning to the processor data from the at least part of the one or more tiles stored in the tile-aware cache.

6. The method of claim 1, further comprising:
receiving at the address aperture a first data write request from the processing component;
in response to receiving the first data write request, the address aperture determining a tile-based address in the alias address region of the memory component having a tile-based address structure, wherein the tile-based address is associated with one or more tiles that will be written to in service of the first data write request;
the address aperture determining that service of the first data write request would require one or more partial tile writes;
in response to determining that service of the first data write request would require one or more partial tile writes, the address aperture storing data from the first data write request in the tile-aware cache.

7. The method of claim 6, further comprising:
receiving at the address aperture a second data write request from the processing component;
in response to receiving the second data write request, the address aperture assembling data from the second data write request with data from the first data write request, wherein assembling data from the second data write request with data from the first data write request generates an assembled write transaction comprising one or more full tiles of data; and
writing the assembled write transaction to the alias address region of the memory component having a tile-based address structure.

8. A system for intelligent tile-based memory bandwidth management in a portable computing device (“PCD”), the system comprising:
an address aperture configured to:
receive a first data read request from a processing component, wherein the first data read request is associated with a first linear aperture address;
in response to receiving the first data read request, determine a tile-based address in an alias address region of a memory component having a tile-based address structure, wherein the tile-based address is associated with one or more tiles containing data needed for service of the first data read request;
determine whether the one or more tiles are stored in a tile-aware cache of the address aperture; and
if the one or more tiles are stored in the tile-aware cache of the address aperture, respond to the first data read request by returning to the processor data from the one or more tiles stored in the tile-aware cache.

9. The system of claim 8, wherein the address aperture comprises a codec and the data from the one or more tiles stored in the tile-aware cache is decompressed before being returned to the processor.

10. The system of claim 8, wherein the address aperture is further configured to:
if the one or more tiles are unavailable in the tile-aware cache of the address aperture, respond to the first data read request by reading the one or more tiles from the memory component and return to the processor data from the one or more tiles read from the memory component.

11. The system of claim 10, wherein the address aperture is further configured to:
store at least part of the one or more tiles in the tile-aware cache, wherein the at least part of the one or more tiles was not required for service of the first read request.

12. The system of claim 11, wherein the address aperture is further configured to:
receive a second data read request from the processing component, wherein the second data read request is associated with a second aperture address; and
respond to the second data read request by returning to the processor data from the at least part of the one or more tiles stored in the tile-aware cache.

13. The system of claim 8, wherein the address aperture is further configured to:
receive a first data write request from the processing component;
in response to receiving the first data write request, determine a tile-based address in the alias address region of the memory component having a tile-based address structure, wherein the tile-based address is associated with one or more tiles that will be written to in service of the first data write request;
determine that service of the first data write request would require one or more partial tile writes;
in response to determining that service of the first data write request would require one or more partial tile writes, store data from the first data write request in the tile-aware cache.

14. The system of claim 13, wherein the address aperture is further configured to:
receive a second data write request from the processing component;
in response to receiving the second data write request, assemble data from the second data write request with data from the first data write request, wherein assembling data from the second data write request with data from the first data write request generates an assembled write transaction comprising one or more full tiles of data; and
write the assembled write transaction to the alias address region of the memory component having a tile-based address structure.

15. The system of claim 8, wherein the PCD is in the form of a wireless telephone.

16. A system for intelligent tile-based memory bandwidth management in a portable computing device (“PCD”), the method comprising:
means for receiving a first data read request from a processing component, wherein the first data read request is associated with a first linear aperture address;
means for, in response to receiving the first data read request, determining a tile-based address in an alias address region of a memory component having a tile-based address structure, wherein the tile-based address is associated with one or more tiles containing data needed for service of the first data read request;
means for determining whether the one or more tiles are stored in a tile-aware cache; and
means for, if the one or more tiles are stored in the tile-aware cache, responding to the first data read request by returning to the processor data from the one or more tiles stored in the tile-aware cache.

17. The system of claim 16, further comprising means for compressing and decompressing data and the data from the one or more tiles stored in the tile-aware cache is decompressed before being returned to the processor.

18. The system of claim 16, further comprising:
means for, if the one or more tiles are unavailable in the tile-aware cache of the address aperture, responding to the first data read request by reading the one or more tiles from the memory component and returning to the processor data from the one or more tiles read from the memory component.

19. The system of claim 18, further comprising:
means for storing at least part of the one or more tiles in the tile-aware cache, wherein the at least part of the one or more tiles was not required for service of the first read request.

20. The system of claim 19, further comprising:
means for receiving a second data read request from the processing component, wherein the second data read request is associated with a second aperture address; and
means for responding to the second data read request by returning to the processor data from the at least part of the one or more tiles stored in the tile-aware cache.

21. The system of claim 16, further comprising:
means for receiving a first data write request from the processing component;
means for, in response to receiving the first data write request, determining a tile-based address in the alias address region of the memory component having a tile-based address structure, wherein the tile-based address is associated with one or more tiles that will be written to in service of the first data write request;
means for determining that service of the first data write request would require one or more partial tile writes;
means for, in response to determining that service of the first data write request would require one or more partial tile writes, storing data from the first data write request in the tile-aware cache.

22. The system of claim 21, further comprising:
means for receiving a second data write request from the processing component;
means for, in response to receiving the second data write request, assembling data from the second data write request with data from the first data write request, wherein assembling data from the second data write request with data from the first data write request generates an assembled write transaction comprising one or more full tiles of data; and
means for writing the assembled write transaction to the alias address region of the memory component having a tile-based address structure.

23. The system of claim 16, wherein the PCD is in the form of a wireless telephone.

24. A computer program product comprising a computer usable medium having a computer readable program code embodied therein, said computer readable program code adapted to be executed to implement a method for intelligent tile-based memory bandwidth management in a portable computing device (“PCD”), said method comprising:
receiving at an address aperture a first data read request from a processing component, wherein the first data read request is associated with a first linear aperture address;
in response to receiving the first data read request, the address aperture determining a tile-based address in an alias address region of a memory component having a tile-based address structure, wherein the tile-based address is associated with one or more tiles containing data needed for service of the first data read request;
the address aperture determining whether the one or more tiles are stored in a tile-aware cache of the address aperture; and
if the one or more tiles are stored in the tile-aware cache of the address aperture, the address aperture responding to the first data read request by returning to the processor data from the one or more tiles stored in the tile-aware cache.

25. The computer program product of claim 24, wherein the address aperture comprises a codec and the data from the one or more tiles stored in the tile-aware cache is decompressed before being returned to the processor.

26. The computer program product of claim 24, further comprising:
if the one or more tiles are unavailable in the tile-aware cache of the address aperture, the address aperture responding to the first data read request by reading the one or more tiles from the memory component and returning to the processor data from the one or more tiles read from the memory component.

27. The computer program product of claim 26, further comprising:
storing at least part of the one or more tiles in the tile-aware cache, wherein the at least part of the one or more tiles was not required for service of the first read request.

28. The computer program product of claim 27, further comprising:
receiving at the address aperture a second data read request from the processing component, wherein the second data read request is associated with a second aperture address; and
the address aperture responding to the second data read request by returning to the processor data from the at least part of the one or more tiles stored in the tile-aware cache.

29. The computer program product of claim 24, further comprising:
receiving at the address aperture a first data write request from the processing component;
in response to receiving the first data write request, the address aperture determining a tile-based address in the alias address region of the memory component having a tile-based address structure, wherein the tile-based address is associated with one or more tiles that will be written to in service of the first data write request;
the address aperture determining that service of the first data write request would require one or more partial tile writes;
in response to determining that service of the first data write request would require one or more partial tile writes, the address aperture storing data from the first data write request in the tile-aware cache.

30. The computer program product of claim 29, further comprising:
receiving at the address aperture a second data write request from the processing component;
in response to receiving the second data write request, the address aperture assembling data from the second data write request with data from the first data write request, wherein assembling data from the second data write request with data from the first data write request generates an assembled write transaction comprising one or more full tiles of data; and
writing the assembled write transaction to the alias address region of the memory component having a tile-based address structure.
